(19) United States
(12) Patent Application Publication
(10) Pub. No.: US 2007/0261235 A1
(43) Pub. Date: Nov. 15, 2007

(54) Electronic device removal tool and carrier

(75) Inventors: Charles J. Byrd, Snow Camp, NC (US); Brian W. Killebrew, Raleigh, NC (US); Edward A. Shumpert JR., Raleigh, NC (US)

Correspondence Address: DRIGGS, HOGG & FRY CO., L.P.A., 38500 CHARDON ROAD, DEPT. LEN, WILLOUGHBY HILLS, OH, 44094, US

(73) Assignee: Lenovo (Singapore) Pte. Ltd., Singapore (SG)

(21) Appl. No.: 11/413,237

(22) Filed: Apr. 29, 2006

(51) Int. Cl. H05K 3/30; B23P 19/00

(52) U.S. Cl. 29/832; 29/762; 29/426.5

(57) ABSTRACT

A tool is used for the removal of a processor from a heat sink for replacement or repair, or for delivery of the processor for servicing. The tool combines the features for the removal of the processor from the heat sink and a covered container for storage and delivery of the processor. The tool has at least one recess therein sized to correspond to the shape of the processor. The recess is sufficiently deep to receive the entire processor without damage to any contact pins that may be on the processor surface. The tool has sufficient rigidity to permit the tool and processor to be rotated relative to the heat sink to which the processor is adhered. The portion of the tool that surrounds the processor comprises a suitable ESD resistant material. The tool includes a removable lid layered with an ESD resistant foam for storage and transport.

### FIELD OF THE INVENTION

The present invention relates to the removal and package for an electronic device, for example an electronic processor or other heat generating device, such as a semiconductor chip or other electronic package that is coupled to a heat dissipating device, such as a finned heat sink. More specifically, it relates to a tool that is useful for separating the heat generating device from its corresponding heat sink without damage to the heat generating device. It also relates to the packaging used to transport the electronic device to a remote location to be serviced.

### DESCRIPTION OF THE RELATED ART

During the operation of an electronic device, such as a CPU (central processing unit), the various components thereof generate substantial quantities of heat. The electronic device typically is mounted within a housing, and means must be provided for the removal of the heat from the housing. Overheating of the device reduces the operating efficiency of the system, and ultimately can lead to premature failure of semiconductor chips and other components within the housing. With increasingly faster clock speeds, the amount of waste heat generated is proportional to the increased clock speed. This can lead to increases in the operating temperature of the device, thereby contributing to heat-induced failure.

Generally, heat is dissipated from the housing by circulating cooling air around the components. Also, the electronic device typically is thermally coupled to a heat sink to draw heat from the device. The mere use of mechanical attachments, such as nuts and bolts, clamps or clips, to connect the electronic device to the heat sink generally provides insufficient heat transfer away from the device. Instead, a thermal interface material, such as a grease and/or thermal tape, is often used between the device and the heat sink to provide a more effective thermal coupling.

Although this type of coupling is an effective heat transfer mechanism, it causes problems when the electronic device requires servicing or disassembly. One problem that is particularly troublesome is that the grease and/or thermal tape used for coupling increases the difficulty of separating the heat sink from the electronic device without damaging the device. This is particularly noticeable when performing field maintenance and service on the device. The disassembly is often achieved using a screwdriver or similar device to pry the heat sink from the electronic device. For this purpose, devices such as that described at page 173 of IBM Technical Disclosure Bulletin, dated February 1995, have been used. Some degree of skill is required in their use so as not to cause further damage to the electronic device, resulting in additional repair costs. The problem is particularly troublesome when separating the heat sink from a CPU, such as a Willamette, Willamette-N, Northwood or Prescott CPU containing a processor, such as a Pentium® or a Celeron® chip, or an AMD pin and socket processor. The adhesion between the processor and the heat sink is sufficiently great as to cause separation between the processing unit and its corresponding CPU socket.

Another option in lieu of servicing in the field is to transport the defective electronic device to a central servicing center for disassembly and maintenance. This can greatly increase service costs and the duration of down-time, thereby adversely affecting operating efficiency.

### BRIEF SUMMARY OF THE PRESENT INVENTION

The present invention relates to a disassembly tool that separates a processor, such as a central processing unit, from a heat sink without causing damage to the processor.

The invention further relates to the use of the tool for the disassembly of an electronic device to facilitate servicing, repair or replacement. The tool comprises a holder having a recess with a cross sectional profile corresponding to the periphery of the electronic component. The recess is adapted to closely surround the periphery of the electronic component and is sufficiently deep to receive the entire component. The tool has sufficient rigidity to permit the tool and the electronic component to be rotated relative to the heat sink during disassembly to separate the bond between the electronic device and the heat dissipating device. The tool is made from or includes an ESD (electrostatic discharge) resistant material surrounding the electronic device in the recess. The ESD resistant material can be an anti-static, static dissipative or electrically conductive material. A removable lid fits over the recess and serves to retain the electronic component in the recess for protection during subsequent handling. The lid preferably includes a layer of compressive foam which is also made of an ESD resistant material. When the recess is covered by the lid, the foam contacts the electronic component to cushion the same, thereby preventing damage to the socket pins. In this manner, the tool serves a second purpose as packaging to facilitate the transport of the electronic device to a location for field service or repair.

The invention also relates to a combination removal tool and transport container for an on-chip processor and comprises a holder having a recess therein with a cross sectional profile corresponding to the shape of the processor. The recess is sufficiently deep to receive the entire processor. The tool is sufficiently rugged and has enough rigidity to permit the tool and the processor to be rotated relative to a substrate to which the processor is adhered. The tool utilizes an ESD resistant material surrounding the processor. A removable lid fits over the recess and serves to retain the processor in the recess of the tool for protection during transport and handling. The lid includes a compressive foam layer which also comprises an ESD resistant material, whereupon the foam contacts the face of the processor when the lid is fitted over the removal tool.

Lastly, the invention relates to a method of separating an electronic component from a heat sink or other type of heat dissipater. The processor has an exposed planar surface, a periphery, and a second planar surface which is bonded to a corresponding surface of the heat dissipater. The tool comprises a holder having a recess with sides that correspond to the periphery of the electronic component. The recess is sufficiently deep to receive the entire electronic component. The tool is rigid enough to enable the tool and the electronic component to be rotated relative to the heat dissipating device to sever the bond between the electronic device and the heat dissipating device. The method comprises placing the tool on top of the exposed planar surface of the electronic component so that the sides of the recess contact the periphery of the electronic component. The tool is then twisted to cause the electronic device to rotate relative to the heat dissipater to break the bond between the component and the heat dissipater. The method includes using an ESD resistant material in the tool surrounding the electronic component. A removable lid may be fitted over the recess to retain the processor in the recess of the tool for protection during transport and handling. The lid is lined with a compressive foam layer of an ESD resistant material to contact the processor.

### BRIEF DESCRIPTION OF THE DRAWINGS

The drawings as described herein are presented for the purpose of illustrating the invention, its features, and its environment. However, they are not intended to serve as a limitation on the invention.

FIG. 1 is a planar elevation view of a processor coupled to a heat sink;

FIG. 2 is a perspective view of the tool of the present invention;

FIG. 3 shows the tool positioned over the processor;

FIG. 4 shows the tool engaging the processor and twisted to dislodge it from the heat sink;

FIG. 5 shows the processor positioned within the tool;

FIG. 6 is an elevation of the packaging, showing the lid positioned above the packaging prior to closing;

FIG. 7 shows the package ready for shipping;

FIG. 8 is a top view of a tool showing one sized recess; and

FIG. 9 is a bottom view of the tool showing a different sized recess.

### DETAILED DESCRIPTION OF THE INVENTION

Typically, an electronic device, such as a semiconductor chip, is connected to a socket of a CPU by pins. This subassembly is then thermally coupled to the heat sink using grease or thermal tape, as previously noted, with the chip sandwiched between the heat sink and the socket. In general, the heat sink is formed with a heat receiving interface which is adapted to conform generally to a heat emitting surface of the electronic device so that heat is transferred to the heat sink by conduction. Generally, the heat sink has one or more surfaces through which heat is dissipated by radiation. These heat dissipating surfaces typically include one or more fins or pins to increase the rate of heat dissipation. Furthermore, one or more fans may be played across the fins or pins to increase the ΔT between the electronic device and the heat sink, thereby further aiding in heat dissipation.

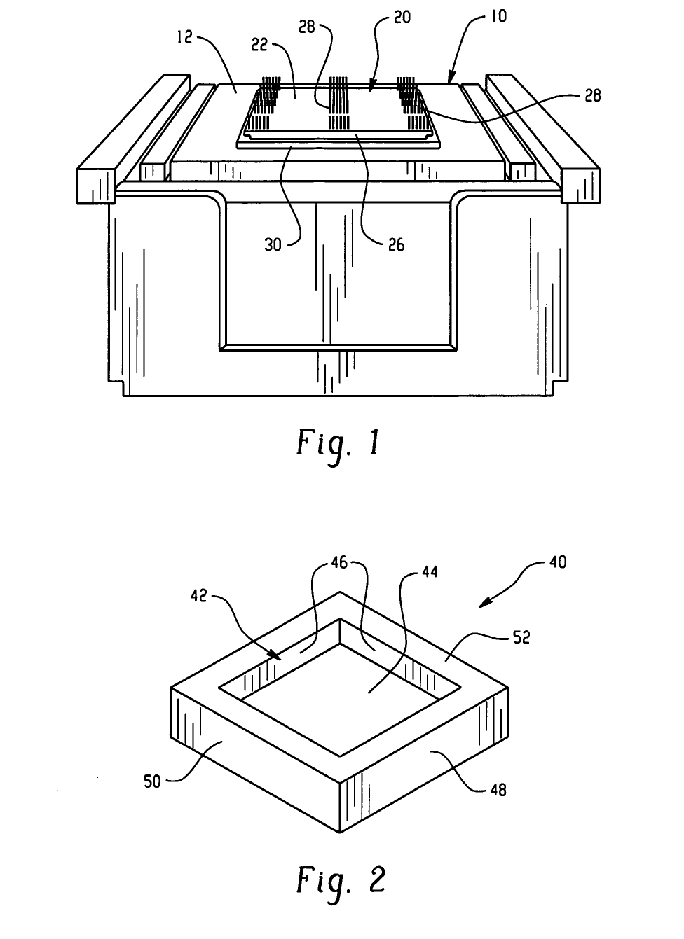

Turning now to the drawings, FIG. 1 shows a heat sink 10 having a heat transfer surface 12, and may also include cooling fins (not shown). An electronic component 20, such as a processor or a CPU, is typically provided with pins 28 on the top surface 22 whereby the component is electrically connected to a socket of a suitable PC board, such as a motherboard. A suitable thermal interface material 30 is applied on the bottom surface of the electronic component 20 to provide good heat transfer when the heat sink 10 is mated to the bottom surface of the electronic component. Suitable materials for the thermal interface material include but are not limited to thermally conductive tapes, pastes, greases, silicones, paraffin, graphite and carbon fibers. The particular choice of thermal transfer material between the heat generating component and the heat sink does not constitute a part of the present invention. However, because of the effectiveness of the bond, difficulty is frequently encountered when attempting to separate the component from the heat sink.

Although not shown nor forming part of the present invention, the heat sink 10 and the PC board generally are clamped together with the electronic component 20 sandwiched therebetween by suitable means, such as one or more pressure plates held in place by bolts threaded into one of the plates, or passing through the plates and secured with nuts. Alternatively, various types of proprietary clips or other fasteners can be used to secure the heat sink to the electronic component and PC board.

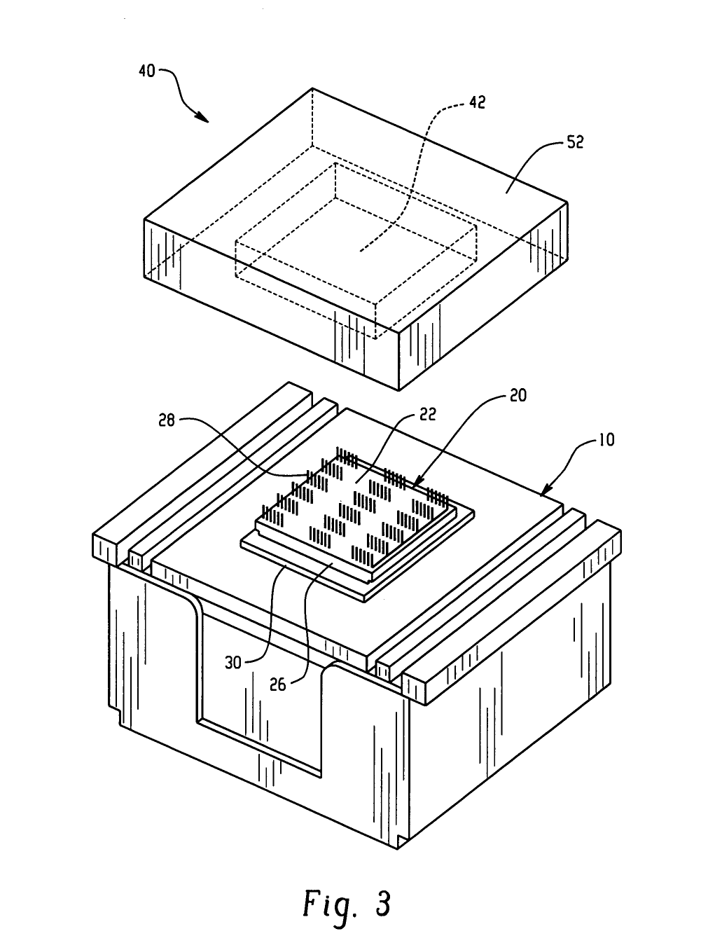

The tool 40 of the present invention is shown in perspective in FIG. 2. This particular iteration of the tool shows it as a rectangular cube, with sides 48 and 50 and top surface 52 being shown. The tool 40 includes a recess 42, defined by the sides 46 and the bottom 44. Both the sides and the bottom preferably comprise an ESD resistant material.

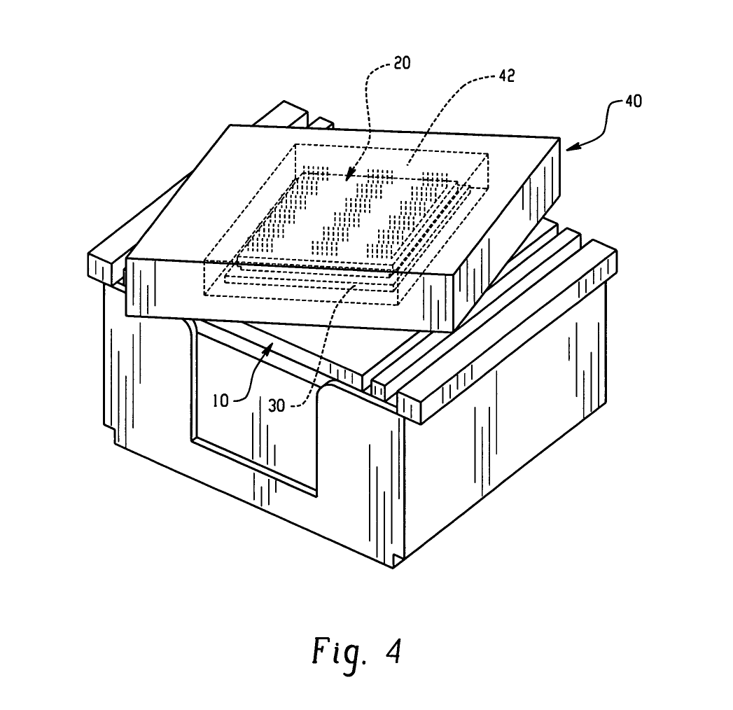

Details of the operation of the present invention are shown in FIGS. 3 and 4. FIG. 3 shows the tool 40 prior to engaging the electronic component 20 that is bonded to the heat sink 10 by bonding layer 30. As will be noted, the tool recess 42 is sized to surround the periphery 26 of the electronic component 20, and is sufficiently deep to totally accept the component and the exposed pins 28. The bond between the electronic component 20 and the heat sink 10 is broken by rotating the tool as shown in FIG. 4 while holding or securing the heat sink to prevent its rotation. In this manner, sufficient rotational torque can be applied to the periphery of the component to break the bond without any pressure being applied directly to the pins. This serves to avoid bending or breaking the pins during disassembly.

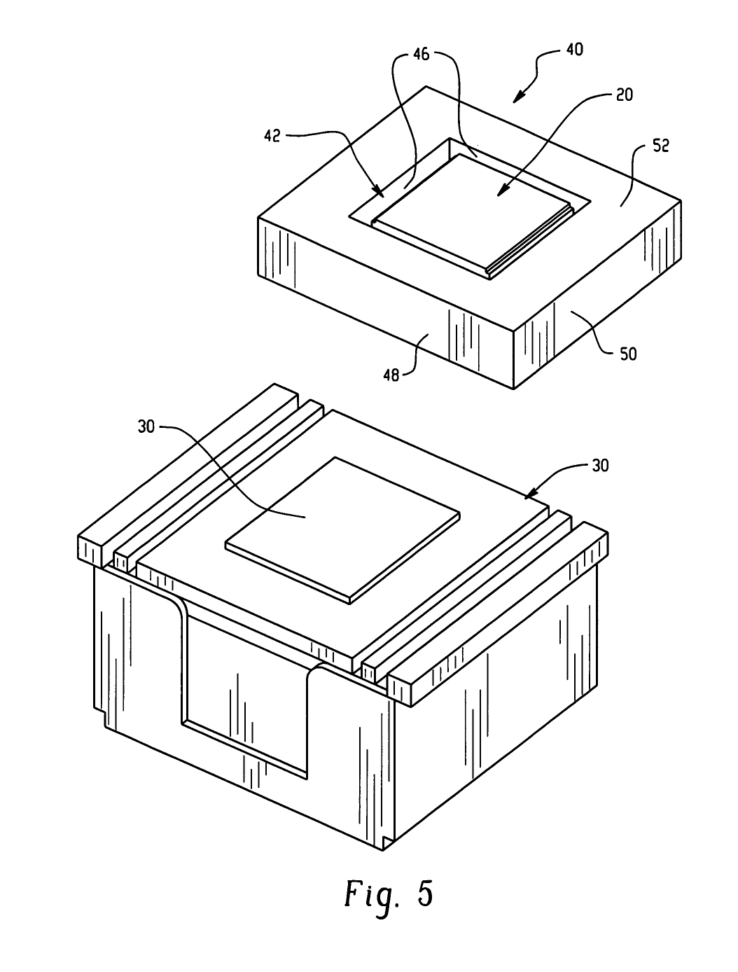

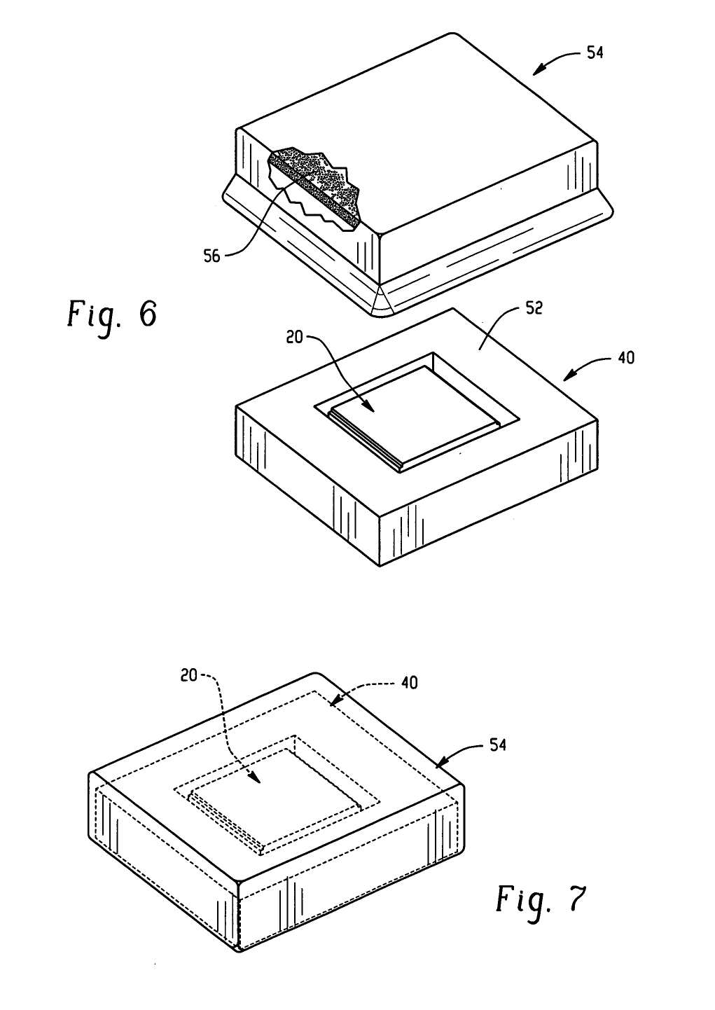

After the electronic component 20 is separated from the heat sink 10, the component is positioned within the tool 40 as seen in FIG. 5 for further handling. In the event that the electronic component 20 is to be transported or shipped to a different location for maintenance or repair, then a lid 54 as seen in FIG. 6 is placed over the component for further handling. The inside of the lid is covered with a layer 56 of ESD resistant foam. As shown in FIG. 7, the lid 54 is fitted onto the top 52 of the tool 10 over the electronic component 20, with the foam layer 56 contacting the top of the component. This provides a cushion to minimize pressure on the pins and to prevent movement of the component 20 within the recess. The lid 54 can be secured to the tool using binding tape, twine, or other suitable packaging means. Alternatively, the tool or the lid can be provided with a lip adapted to mate with and securely engage a groove in the lid or tool, respectively.

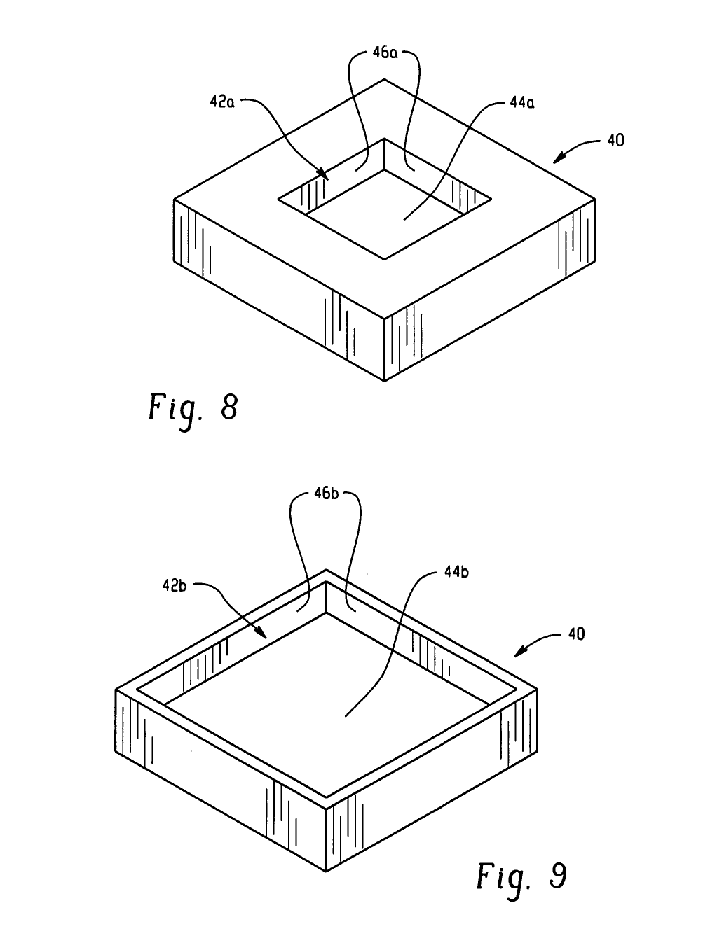

As shown in the previous figures, the tool is in the shape of a rectangular block having a recess in one face of the block. Recognizing that the tool should be versatile enough to fit over processors of differing sizes, the invention contemplates that the face of the tool opposite the face with a first recess can likewise include a recess having different dimensions in cross section and/or depth. This is shown in FIGS. 8 and 9. FIG. 8 shows a tool 40 with a relatively small recess 42a defined by bottom 44a and sides 46a. FIG. 9 shows the opposite side of the tool 40 containing a second recess 42b defined by bottom 44b and sides 46b. The cross sections of the two recesses 42a, 42b are different so that they can optionally be used for the removal and storage of two processors having different cross sectional profiles. One sized lid would be suitable for use as a cover over the recess in either side.

As yet another variation of the invention, one or more of the remaining sides of the tool may likewise include recesses that are uniquely dimensioned so as to be usable on commercially available or proprietary processors having their own unique dimensional specifications. This embodiment may then require a supply of multiple lids to accommodate the different sizes of the sides, unless the tool is in the shape of a rectangular parallelepiped in which the dimensions of all six sides are equal.

While the invention has been described in combination with specific embodiments, there are many alternatives, modifications, and variations that are likewise deemed to be within the scope thereof. Accordingly, the invention is intended to embrace all such alternatives, modifications and variations as fall within the spirit and scope of the appended claims.

What is claimed is:

1. A tool for separating an electronic component having an exposed planar surface and a periphery from a heat dissipating device to which a second planar surface of said electronic component is bonded, said tool comprising a holder having a recess with a cross sectional profile corresponding to the periphery of the electronic component, and adapted to closely surround the periphery of the electronic component, said recess being sufficiently deep to receive the entire electronic component, the tool having sufficient rigidity to permit the tool and the electronic component to be rotated relative to the heat dissipating device to sever the bond between the electronic device and the heat dissipating device.

2. The tool according to claim 1 wherein the recess comprises an ESD resistant material.

3. The tool according to claim 2 wherein the ESD resistant material is selected from the group consisting of anti-static, static dissipative and electrically conductive materials.

4. The tool according to claim 3 wherein the ESD material is selected from the group consisting of wood, polymeric material comprising polyamide-imide, polyeteraflouroethylene, polyetherketone, polyetherimide, polyether sulfone, polyvinylidene fluoride, acetal copolymeracrylic polyvinylchloride alloy, acetal, polypropylene, acrylonitrile-butadiene-styrene, polyethylene, polycarbonate and polyvinylchloride, polycarbonate, and combinations thereof.

5. The tool according to claim 5 further including a lid that fits over the recess and serves to retain the electronic component in the recess for protection.

6. The tool according to claim 5 wherein the lid includes a layer of compressive ESD resistant material foam to contact the first planar surface of the electronic component.

7. The tool according to claim 1 wherein more than one side of the holder includes a recess, the size of a first recess corresponding to the size of one electronic component, and the size of each other recess differing in size from the size of the first recess.

8. A combination removal tool and transport container for an on-chip processor comprising a holder having a recess therein with a cross sectional profile corresponding to the shape of the processor and adapted to closely surround the periphery of the electronic component, said recess being sufficiently deep to receive the entire processor, the tool having sufficient rigidity to permit the tool and the processor to be rotated relative to a substrate to which the processor is adhered.

9. The combination according to claim 8 wherein the tool utilizes an ESD resistant material surrounding the processor.

10. The combination according to claim 9 further including a removable lid that fits over the recess and serves to retain the processor in the recess of the tool for protection during transport and handling.

11. The combination according to claim 10 wherein the lid includes a compressive foam layer of ESD resistant material to contact the processor.

12. The combination according to claim 11 wherein the ESD resistant material in the lid and in the recess is selected from the group of anti-static, static dissipative, and conductive materials.

13. The combination according to claim 8 wherein more than one side of the holder includes a recess, the size of the first recess corresponding to one processor having a first cross sectional size, and the size of each other recess differing in size from the size of the first recess to accommodate processors having a different cross dimensional size than those of the first processor.

14. A method of separating an electronic component having an exposed planar surface and a second planar surface, and a periphery, from a heat dissipating device to which the second planar surface is bonded, wherein said tool comprises a holder having a recess with sides having a cross sectional profile corresponding to the periphery of the electronic component, said recess being sufficiently deep to receive the entire electronic component, and said tool having sufficient rigidity to permit the tool and the electronic component to be rotated relative to the heat dissipating device to sever the bond between the electronic device and the heat dissipating device, comprising the steps of:
a. placing the tool on top of the exposed planar surface of the electronic component so that the sides of the recess contact the periphery of the electronic component, and
b. twisting the tool to cause the electronic device to rotate relative to the heat dissipating device to break the bond between the component and the heat dissipating device.

15. The method according to claim 14 including the step of surrounding the processor with an ESD resistant material before contact with the processor.

16. The method according to claim 14 further including the step of fitting a removable lid over the tool to retain the processor in the recess of the tool for protection during transport and handling.

17. The method according to claim 16 including the step of providing the lid with a layer of compressive ESD resistant foam to contact the processor when the lid is placed over the holder.

18. The method according to claim 12 further including the step of providing more than one side of the holder with a recess, the size of a first recess corresponding to the size of one electronic component, and the size of each other recess differing in size from the size of the first recess.
